(19) United States
(12) Patent Application Publication
(10) Pub. No.: US 2017/0069563 A1
(43) Pub. Date: Mar. 9, 2017

(54) SEMICONDUCTOR PACKAGE AND METHOD OF MANUFACTURING SEMICONDUCTOR PACKAGE

(71) Applicant: KABUSHIKI KAISHA TOSHIBA, Tokyo (JP)

(72) Inventor: Takeshi MIYAKAWA, Kanazawa Ishikawa (JP)

(21) Appl. No.: 15/057,039

(22) Filed: Feb. 29, 2016

(30) Foreign Application Priority Data
Sep. 4, 2015 (JP) 2015-174622

(51) Int. Cl. H01L 23/492; H01L 23/29; H01L 21/66; H01L 23/00; H01L 23/31

(52) U.S. Cl. CPC H01L 23/4924; H01L 24/33; H01L 23/3107; H01L 24/83; H01L 22/14; H01L 23/293; H01L 2224/32245; H01L 2224/33181; H01L 2924/17747; H01L 2924/10253; H01L 2924/10272; H01L 2924/1033; H01L 2924/10329; H01L 29/45

(57) ABSTRACT

A semiconductor package includes a first metal plate having a first surface, a semiconductor chip including a first electrode and a second electrode, on the first surface, and a second metal plate on the semiconductor chip. The first metal plate has a first surface. The first electrode is connected to the first metal plate. The second metal plate includes a second surface and first and second side surfaces respectively on opposite sides of the second metal plate and connected to the second surface. The first side surface has a first recessed portion extending in a direction which crosses the first and second surfaces, and the second side surface has a second recessed portion extending in the second direction that crosses the first and second surfaces.

### CROSS-REFERENCE TO RELATED APPLICATION

This application is based upon and claims the benefit of priority from Japanese Patent Application No. 2015-174622, filed Sep. 4, 2015, the entire contents of which are incorporated herein by reference.

### FIELD

Exemplary embodiments described herein relate to a semiconductor package and a method of manufacturing the semiconductor package.

### BACKGROUND

There is a semiconductor package in which a semiconductor chip is provided between two metal plates via a connection portion. In order to enhance heat dissipation performance of the semiconductor package, an exposed area of each of the metal plates should be increased. Meanwhile, the thickness of the connection portion affects reliability of the semiconductor package, and thus, the thickness of the connection portion of the assembled semiconductor package needs to be measured. However, when the area of the metal plate is increased, the measurement of the thickness of the connection portion between each of the metal plates and the semiconductor chip cannot be easily performed.

### DESCRIPTION OF THE DRAWINGS

FIG. 1 is a plan view of a semiconductor package according to an embodiment.

FIG. 2A is a sectional view taken along line IIA-IIA in FIG. 1, and FIG. 2B is a sectional view taken along line IIB-IIB in FIG. 1.

FIGS. 3-6 are plan views illustrating manufacturing steps of the semiconductor package according to the embodiment.

FIGS. 7A and 7B are schematic views illustrating a portion of the semiconductor package according to Modification Example of the embodiment.

### DETAILED DESCRIPTION

Embodiments provide a semiconductor package which enables easy measurement of the thickness of a connection portion and a method of manufacturing the semiconductor package.

In general, according to one embodiment, there is provided a semiconductor package including a first metal plate having a first surface, a semiconductor chip including a first electrode and a second electrode, on the first surface, and a second metal plate. The first electrode of the semiconductor chip is connected to the first metal plate. The second metal plate has a second surface and first and second side surfaces respectively on opposite sides of the second metal plate and connected to the second surface, and is connected to the second electrode. The first side surface has a first recessed portion extending in a direction which crosses the first and second surfaces, and the second side surface has a second recessed portion extending in the second direction that crosses the first and second surfaces.

Hereinafter, the respective embodiments will be described with reference to the drawings.

In addition, the drawings are schematic or conceptual, and thus the relationship between the thickness and the width of each portion, and the size ratio between portions are not necessarily the same as the actual ones. Moreover, the same components, dimensions and ratios may be illustrated differently depending on the drawings in some cases.

In the disclosure, the same components which have already been described are given the same reference numerals, and the specific description of the same components will be repeated as needed.

An XYZ orthogonal coordinate system is used in the description of the respective embodiments. Two directions which are parallel to a first surface S1 of a first metal plate 1 and are orthogonal to each other are referred to as an X-direction and a Y-direction. In addition, a direction which is perpendicular to the X-direction and Y-direction is referred to as a Z-direction.

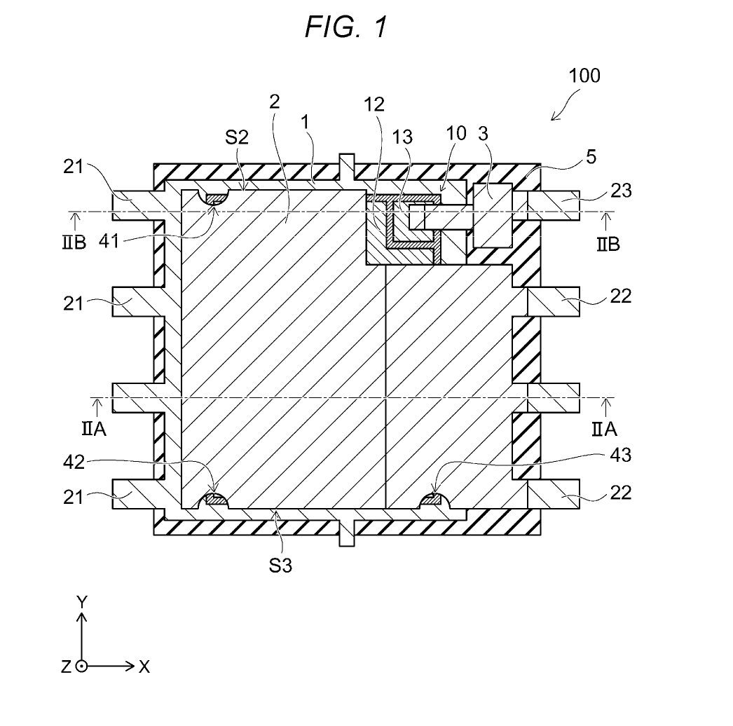

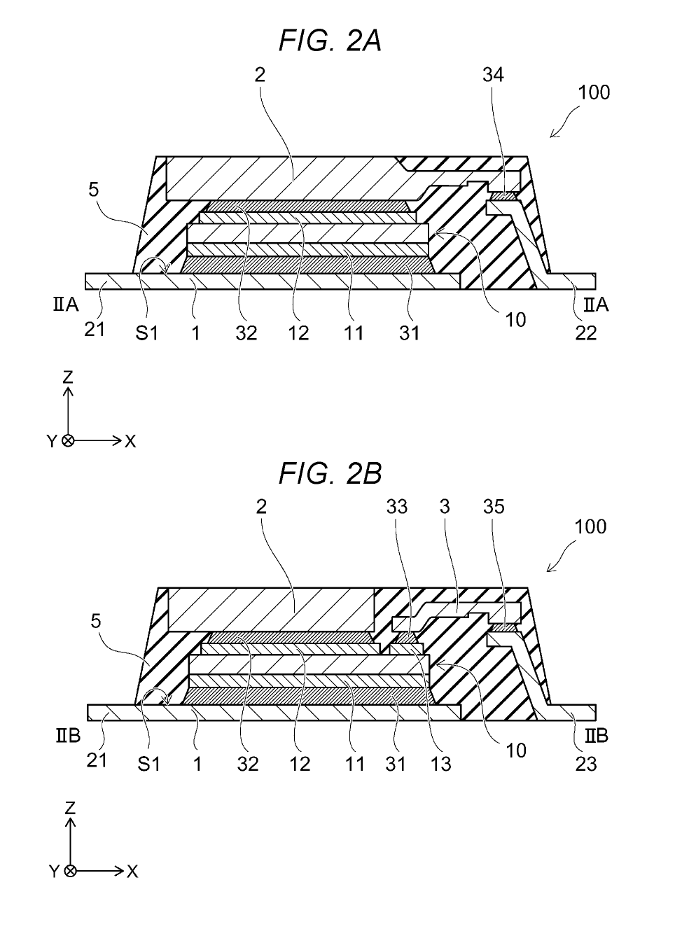

A semiconductor package according to an embodiment will be described with reference to FIG. 1 and FIGS. 2A and 2B.

FIG. 1 is a plan view of a semiconductor package 100 according to the embodiment.

FIG. 2A is a sectional view taken along line IIA-IIA in FIG. 1, and FIG. 2B is a sectional view taken along line IIB-IIB in FIG. 1.

Note that, a portion of a sealing portion 5 is omitted in FIG. 1 so as to illustrate the internal structure of the semiconductor package 100.

As illustrated in FIG. 1 and FIGS. 2A and 2B, the semiconductor package 100 includes a first metal plate 1, a second metal plate 2, a metallic member 3, the sealing portion 5, a semiconductor chip 10, a first lead terminal 21, a second lead terminal 22, and a third lead terminal 23.

As illustrated in FIGS. 2A and 2B, the semiconductor chip 10 is provided on a first surface S1 of the first metal plate 1. The semiconductor chip 10 is formed in, for example, a rectangular shape, and includes a first electrode 11, a second electrode 12, and a third electrode 13 (shown in FIG. 1 and FIG. 2B). The second electrode 12 and the third electrode 13 are spaced from each other on the side of the semiconductor chip 10 opposite to the location of the first electrode 11 on the semiconductor chip 10. The first electrode 11 is connected to the first metal plate 1 through a first connection portion 31.

As illustrated in FIG. 2A, the second metal plate 2 is provided on the semiconductor chip 10, and is connected to the second electrode 12 through a second connection portion 32.

As illustrated in FIG. 1 and FIG. 2B, the metallic member 3 is provided on the semiconductor chip 10, and is isolated from the second metal plate 2. The metallic member 3 is connected to the third electrode 13 by a third connection portion 33.

The first lead terminal 21 is connected to the first metal plate 1. A plurality of the first lead terminals 21 are provided and are spaced apart in a Y-direction, and each of the first lead terminals 21 extend from the metal plate 1 in the X-direction. In the example illustrated in FIG. 1, the first metal plate 1 and the first lead terminal 21 are integrally formed with each other, but the first metal plate 1 and the first lead terminal 21 may be formed of different members. In the latter case, the first metal plate 1 and the first lead terminal 21 are connected to each other by using a solder or a conductive bonding material.

The second lead terminal 22 is connected to the second metal plate 2 by a fourth connection portion 34. A plurality of second lead terminals 22 are arranged spaced apart in the Y-direction, and each of the second lead terminals 22 extends from the fourth connection portion 34 in the X-direction.

The third lead terminal 23 is connected to the metallic member 3 by a fifth connection portion 35, and extends from the fifth connection portion 35 in the X-direction.

The second metal plate 2 and the second lead terminal 22 may be integrally formed with each other without being limited to the examples illustrated in FIG. 1 and FIGS. 2A and 2B, and the metallic member 3 and the third lead terminal 23 may be also integrally formed with each other. In addition, the second lead terminal 22 and the third lead terminal 23 may extend in the direction which is different from the direction in which the first lead terminal 21 extends.

The number of the first lead terminals 21, the number of the second lead terminals 22, and the number of the third lead terminals 23 are optionally determined without being limited to the example illustrated in FIG. 1.

In addition, each of the first lead terminal 21, the second lead terminal 22, and the third lead terminal 23 may include a portion which is bent in the middle thereof.

The sealing portion 5 is provided on the first metal plate 1 and in the vicinity of the first metal plate 1, and covers the semiconductor chip 10, a portion of each of the first lead terminals 21 to the third lead terminal 23, and a portion of the second metal plate 2.

Next, a second metal plate 2 will be described in detail.

As illustrated in FIG. 1, the second metal plate 2 has a perimeter surface, including a second surface S2 and a third surface S3 on opposite sides thereof. The second surface S2 and the third surface S3 extend to cross the Y-direction, and extends in the X-Z plane and connect the front and back surfaces of the second metal plate 2.

A first cutout or recessed portion 41 is formed on the second surface S2, and a second cutout portion 42 and a third cutout portion 43 are formed on the third surface S3. The first cutout portion 41 and the second cutout portion 42 are aligned in the Y-direction, and the second cutout portion 42 and the third cutout portion 43 are aligned in the X-direction.

The first to third cutout portions 41 to 43 extend through the second metal plate 2 in the Z-direction. More specifically, the first cutout portion 41 is formed from one side to the other side of the second surface S2 in the Z-direction. The second cutout portion 42 and the third cutout portion 43 are formed from one side to the other side of the third surface S3 in the Z-direction. That is, the first cutout portion 41 is formed from an upper side to a lower side of the second surface S2, and the second cutout portion 42 and the third cutout portion 43 are formed from an upper side to a lower side of the third surface S3.

The first to third cutout portions 41 43 are filled with the sealing portion 5.

A portion of each of the first to third cutout portions 41 to 43 and a side surface of the semiconductor chip 10 are arranged to be on a same line in parallel with the Z-direction respectively. In other words, a portion of the surface forming each of the first cutout portions 41 to 43 and a side surface of the semiconductor chip 10 are arranged to be on a same line in parallel with the Z-direction respectively.

That is, when the semiconductor package 100 is viewed from the Z-direction through the sealing portion 5, the second metal plate 2 is formed such that the top surface of the semiconductor chip 10 is exposed through the first to third cutout portions 41 to 43.

In addition, the second metal plate 2 and the metallic member 3 are spaced from each other on the semiconductor chip 10 in the X-direction and the Y-direction. For this reason, when the semiconductor package 100 is viewed from the Z-direction through the sealing portion 5, it is possible to view the top surface of the semiconductor chip 10 through a gap between the second metal plate 2 and the metallic member 3.

Here, examples of materials of the respective configuring components will be described.

The first metal plate 1, the second metal plate 2, the metallic member 3, and the first lead terminal 21 to the third lead terminal 23 includes metal such as copper.

The semiconductor chip 10 includes a semiconductor element which mainly contains silicon, silicon carbide, gallium nitride, or gallium arsenide.

The first electrode 11 to the third electrode 13 contains a metallic material such as aluminum.

The first connection portion 31 to the fifth connection portion 35 contains a solder material.

The sealing portion 5 contains an insulating resin such as an epoxy resin.

Next, an example of a method of manufacturing the semiconductor package according to the embodiment will be described.

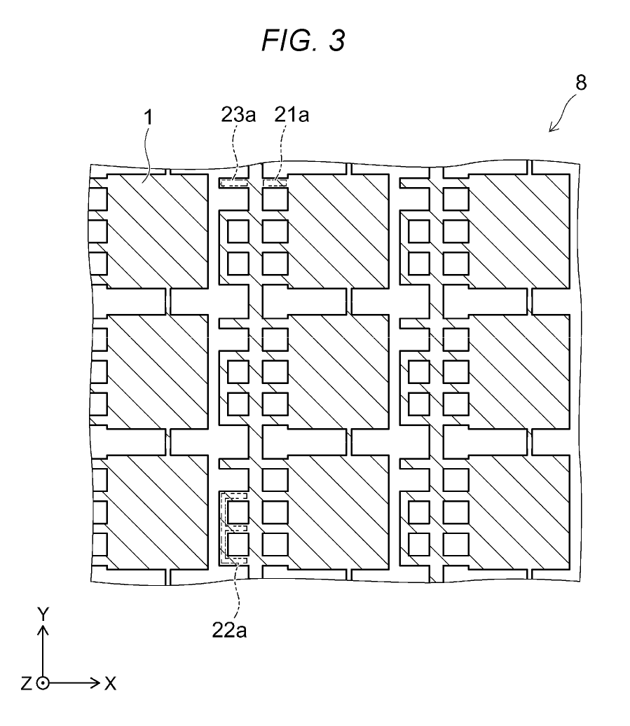

FIG. 3 to FIG. 6 are plan views illustrating manufacturing steps of the semiconductor package 100 according to the embodiment.

First, as illustrated in FIG. 3, a frame 8 which includes a plurality of first metal plates 1 is prepared. The frame 8 further includes portion 21a, 22a and 23a, each of which corresponds to the first lead terminal 21, the second lead terminal 22 and the third lead terminal 23. While the portion 21a comes into contact with the first metal plate 1, the portion 22a and portion 23a are spaced from the first metal plate in the X-direction. In the frame 8, the first metal plate 1, and the portions 21a to 23a are arranged in the X-direction and the Y-direction.

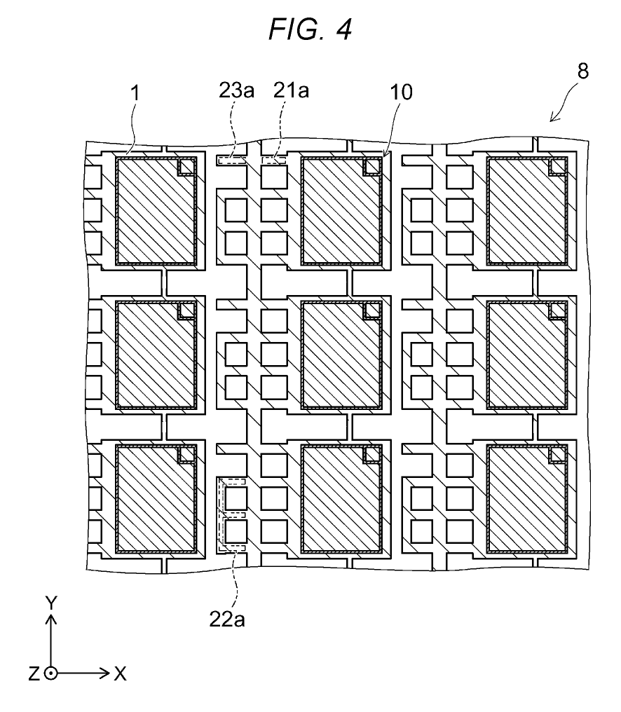

Next, as illustrated in FIG. 4, the semiconductor chip 10 is positioned on each of the first metal plates 1. At this time, the first electrode 11 of the semiconductor chip 10 and the first metal plate 1 are connected to each other via the first connection portion 31.

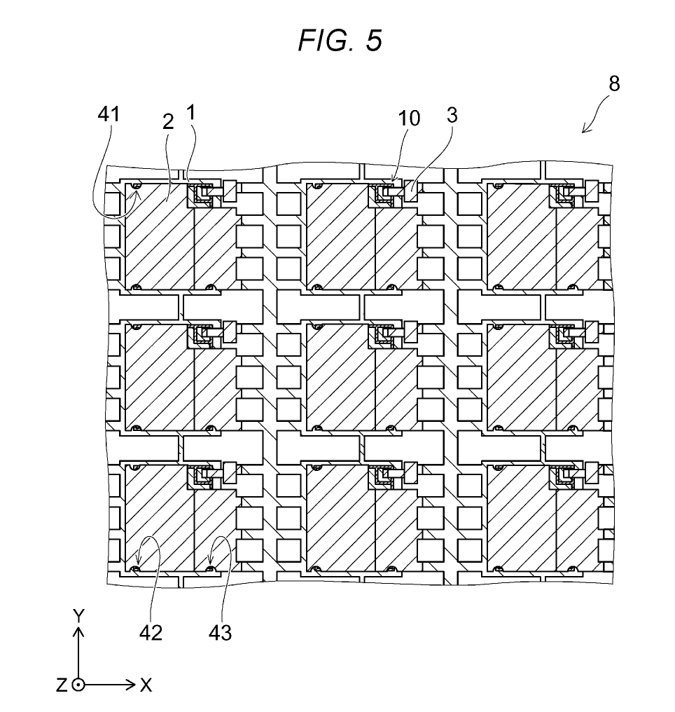

Next, as illustrated in FIG. 5, the second metal plate 2 and the metallic member 3 are located on each of the semiconductor chips 10. At this time, the second metal plate 2 is connected to the second electrode 12 and the portion 22a by the second connection portion 32 and the fourth connection portion 34, respectively. In addition, the metallic member 3 is connected to the third electrode 13 and the portion 23a by the third connection portion 33 and the fifth connection portion 35, respectively.

Further, the first to third cutout portions 41 to 43 are formed on the second metal plate 2, as described above. The second metal plate 2 is positioned such that a portion of each of the first to third cutout portions 41 to 43 and the side end surface of the semiconductor chip 10 are on a same line in parallel with the Z-direction respectively. At this time, the second metal plate 2 is desirably positioned such that the first to third cutout portions 41 to 43 are respectively adjacent to the corners of the semiconductor chip 10 in the Z-direction.

After positioning the second metal plate 2, the position of the semiconductor chip 10 is measured in plural places through the first cutout portion 41 to the third cutout portion 43.

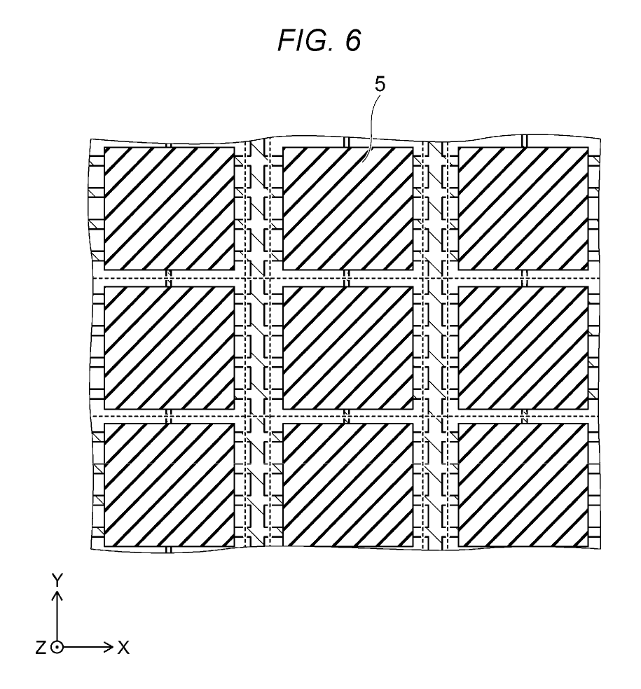

Next, as illustrated in FIG. 6, the sealing portions 5 are formed on the frame 8 to cover each of the semiconductor chip 10 and the second metal plate 2. Each sealing portion 5 is arranged to be spaced apart from other sealing portions 5 such that a portion of each of the portions 21a to 23a are exposed through the sealing portions 5.

Subsequently, the top surface of the sealing portion 5 is ground until the top surface of the second metal plate 2 is exposed. Thereafter, the semiconductor package 100 illustrated in FIG. 1 and FIGS. 2A and 2B can be obtained by cutting the frame 8 at a position shown by a dashed line in FIG. 6.

Meanwhile, operations and effects in the embodiment will be described.

In a case where the semiconductor package 100 is repeatedly heated and cooled in the, it is likely that cracks occur in a portion thereof having a relatively small thickness. This phenomenon is most commonly occurs in the first connection portion 31 and the second connection portion 32 which have a large contact area between each metal plate and the semiconductor chip 10. When the cracks occur in these connection portions, the conductivity is deteriorated, and thus it is likely that an operation failure of the semiconductor package occurs.

For this reason, it is desired to measure the thickness of the connection portion, and to scan for confirming whether or not a portion having small thickness is locally present in the connection portion. On the other hand, in order to enhance heat dissipation performance, when an area of the first metal plate 1 and an area of the second metal plate 2 are increased, the connection portion is hidden between the metal plates, and thus the measurement of the thickness of the connection portion cannot be easily performed.

In contrast, in the semiconductor package of the embodiment, the first cutout portion 41 and the second cutout portion 42 are formed on the second metal plate 2. When forming the first cutout portion 41 and the second cutout portion 42 on the second metal plate 2, the measurement of the position of the top surface of the semiconductor chip 10 is easily performed through the cutout portions thereof.

It is possible to calculate inclination of the semiconductor chip 10 by measuring at least two positions of the top surface of the semiconductor chip 10 through the first cutout portion 41 and the second cutout portion 42. When calculating the inclination of the semiconductor chip 10, it is possible to estimate the thickness of each point of the thickness of the first connection portion 31 and the thickness of the second connection portion 32.

That is, according to the embodiment, the measurement of the thickness of the connection portion can be easily performed by forming the first cutout portion 41 and the second cutout portion 42 on the second metal plate 2.

In addition, when forming the third cutout portion 43 in addition to the second cutout portion 42 on the third surface S3, through the first cutout portion 41 to the third cutout portion 43, it is possible to detect three positions of the top surface of the semiconductor chip 10. For this reason, it is possible to detect the inclination of the semiconductor chip 10 in X-Z plane and the inclination of the semiconductor chip 10 in Y-Z plane. As a result, it is possible to more accurately measure the thickness of the first connection portion 31 and the thickness of the second connection portion 32.

In addition, in order to more accurately calculate the inclination of the semiconductor chip 10, it is desirable that the position of each corner portion of the semiconductor chip 10 can be measured through the first to third cutout portions 41 to 43. That is, it is desirable that the first to third cutout portions 41 to 43 are adjacent to each corner portion of the semiconductor chip 10 in the Z-direction as illustrated in FIG. 1.

Note that, as illustrated in FIGS. 2A and 2B, when the semiconductor package includes the metallic member 3, and the second metal plate 2 and the metallic member 3 are provided to be separated from each other, it is possible to measure the position of the top surface of the semiconductor chip 10 through the gap between the second metal plate 2 and the metallic member 3.

Accordingly, when the semiconductor package includes the metallic member 3, it is possible to measure the thickness of the first connection portion 31 and the thickness of the second connection portion 32 as long as at least one of the first cutout portion 41 and the second cutout portion 42 is formed. In addition, if both the first cutout portion 41 and the second cutout portion 42 are formed, it is possible to calculate the inclination of the semiconductor chip 10 in X-Z plane and the inclination of the semiconductor chip 10 in Y-Z plane.

On occasion, the semiconductor chip 10 may be bent or warped. In this case, the inclination of the semiconductor chip 10 is not uniform. Accordingly, it is desirable that the position of the top surface of the semiconductor chip 10 is measured though the gap between the second metal plate 2 and the metallic member 3 in addition to the first cutout portion 41 to the third cutout portion 43, and the thickness of the first connection portion 31 and the thickness of the second connection portion 32 in the respective points are optically measured.

In addition, in order to more accurately measure the position of the top surface of the semiconductor chip 10, it is desirable that a portion of each of the first to third cutout portions 41 to 43 and the side end surface of the semiconductor chip 10 are on a same line in parallel with the Z-direction, and are not adjacent to the second connection portion 32 in the Z-direction.

Meanwhile, FIG. 1 and FIGS. 2A and 2B illustrate an example of a case where the semiconductor chip 10 includes three electrodes of the first electrode 11 to the third electrode 13. Examples of such a semiconductor chip 10 include a metal oxide semiconductor field effect transistor (MOSFET) and an insulated gate bipolar transistor (IGBT).

The embodiment is not limited to the aforementioned examples; the semiconductor chip 10 is applicable to a case of a diode including two electrodes. In this case, the semiconductor chip 10 may not include the third electrode, and the semiconductor package 100 may not include the metallic member 3 and the third lead terminal 23.

In addition, in the examples illustrated in FIG. 1 and FIGS. 2A and 2B, the first to third cutout portions 41 to 43 are formed into a semicircular shape. However, the semiconductor package in the embodiment is not limited thereto; for example, the first to third cutout portions 41 to 43 may be formed into a triangular shape or a square shape other than the semicircular shape.

In addition, in addition to the first to third cutout portions 41 to 43, other cutout portions may be formed on the second metal plate 2.

### Modification Example

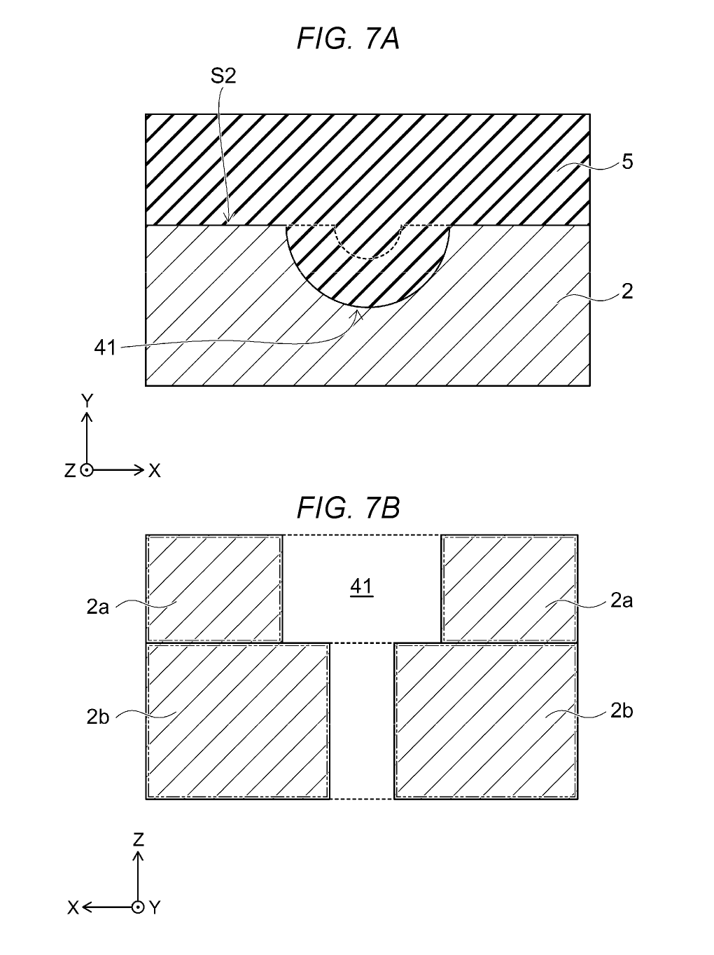

FIG. 7A is a plan view illustrating a portion of the semiconductor package according to Modification Example in the embodiment, and FIG. 7B is a side view illustrating a portion of the semiconductor package according to Modification Example in the embodiment.

FIGS. 7A and 7B illustrate the vicinity of the first cutout portion 41 which is provided on the second surface S2. In addition, FIG. 7A illustrates a portion of a second portion 2b by a dashed line.

As illustrated in FIGS. 7A and 7B, in the semiconductor package according to Modification Example, the second metal plate 2 includes a first portion 2a and the second portion 2b. The first portion 2a and the second portion 2b commonly extend to form a second surface S2. The second portion 2b is positioned between the first portion 2a and the semiconductor chip 10.

The first cutout portion 41, which is formed in the first portion 2a, in the X-direction is longer than the first cutout portion 41, which is formed in the second portion 2b, in the X-direction.

For this reason, a volume of the sealing portion 5 which is provided in the first cutout portion 41 in the first portion 2a is greater than a volume of the sealing portion 5 which is provided in the first cutout portion 41 in the second portion 2b. Further, a portion of the second portion 2b is positioned between a portion of the sealing portion 5 and a portion of another portion in the Z-direction.

With such a configuration, it is possible to increase the contact area between the sealing portion 5 and the second metal plate 2, and to increase the area of the sealing portion 5 which covers the second metal plate 2. For this reason, it is possible to more firmly fix the second metal plate 2 by the sealing portion 5.

As described above, the embodiment is described by exemplifying the first cutout portion 41; however, it is also possible that the structure of the above-described first cutout portion 41 is applied to the second cutout portion 42 and the third cutout portion 43.

Note that, the position of the top surface of the semiconductor chip 10 can be measured by using, for example, a measurement microscope.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

For example, the specific configurations of the respective components of the first metal plate 1, the metallic member, the sealing portion 5, the semiconductor chip 10, the first electrode 11, the second electrode 12, the third electrode 13, the first lead terminal 21, the second lead terminal 22, the third lead terminal 23, the first connection portion 31, the second connection portion 32, the third connection portion 33, the fourth connection portion 34, and the fifth connection portion 35 which are included in the embodiment can be properly selected by those skilled in the art based on a well-known technique. In addition, the above-described embodiments may be combined with each other so as to be executed.

What is claimed is:

1. A semiconductor package comprising:
a first metal plate having a first surface;
a semiconductor chip on the first surface, the semiconductor chip including a first electrode and a second electrode, wherein the first electrode is connected to the first metal plate; and
a second metal plate on the semiconductor chip, wherein the second metal plate has a second surface and first and second side surfaces respectively on opposite sides of the second metal plate and connected to the second surface, and is connected to the second electrode, the first side surface having a first recessed portion extending in a direction which crosses the first and second surfaces, and the second side surface having a second recessed portion extending in the second direction that crosses the first and second surfaces.

2. The package according to claim 1, wherein the first recessed portion extends inwardly of the first side surface and the second recessed portion extends inwardly of the second side surface.

3. The package according to claim 2, wherein a portion of the semiconductor chip is exposed by each of the first and second recessed portions.

4. The package according to claim 3, wherein
the semiconductor chip has sidewalls and at least two corners formed where side walls thereof join;
the first recessed portion is disposed adjacent to, and spaced along one of first and second side surfaces from, a first corner of the semiconductor chip; and
the second cutout is disposed adjacent to, and spaced along one of first and second side surfaces from, a second corner of the semiconductor chip.

5. The package according to claim 1, wherein the first side surface further includes a third recessed portion extending in the second direction that crosses the first and second surfaces.

6. The package according to claim 1, wherein the semiconductor chip further includes a third electrode on a same side of the semiconductor chip as the second electrode and spaced from the second electrode.

7. The package according to claim 6, further comprising:
a metallic member provided on the third electrode and connected to the third electrode,
wherein the metallic member is spaced from the second metal plate.

8. The package according to claim 1, wherein
the second metal plate includes a first portion and a second portion between the first portion and the semiconductor chip, and
the first recessed portion includes a first cutout portion extending through the first portion of the second electrode and a second cutout portion extending through the second portion of the second electrode, the first cutout portion having a larger cutout area than the second cutout portion.

9. The package according to claim 8, wherein the first and second cutouts extend perpendicularly to the first and second surfaces.

10. A semiconductor package comprising:
a first metal plate having a first surface;
a semiconductor chip on the first surface, the semiconductor chip including a first electrode connected to the first metal plate and a second electrode; and
a second metal plate, having perimeter surface, located on the semiconductor chip and connected to the second electrode, the perimeter surface comprising a plurality of recessed portions extending inwardly thereof, wherein
an edge of the semiconductor chip is exposed through the recessed portion.

11. The package according to claim 10,
wherein each of the recessed portions extends through the thickness of the second electrode.

12. The package according to claim 11, wherein
the semiconductor chip includes an edge surface; and
a portion of each of the recessed portions and the edge surface extend along a line perpendicular to an upper surface of the first electrode.

13. The package according to claim 10, wherein
the semiconductor chip includes edge surfaces which form corners; and
a portion of each of the recessed portions overlies one of the corners of the semiconductor chip.

14. The package according to claim 10, wherein
the semiconductor chip further includes a third electrode;
the second electrode and the third electrode are provided on a side of the semiconductor chip opposite to that of the first electrode; and
the second electrode and the third electrode are spaced from each other.

15. The package according to claim 14, further comprising:
a metallic member provided on the third electrode and connected to the third electrode,
wherein the metallic member is spaced from the second metal plate.

16. A method of manufacturing a semiconductor package, comprising:
arranging a semiconductor chip on a first surface of a first metal plate through a first connection portion;
providing a second metal plate having a second surface and first and second side surfaces that are connected to the second surface and are on opposite sides of the second metal plate, the second metal plate having a first cutout inwardly of the first side surface and a second cutout inwardly of the second side surface; and
arranging the second metal plate on the semiconductor chip through a second connection portion, wherein an edge semiconductor chip is exposed through each of the first and second cutouts.

17. The method according to claim 16, wherein the second metal plate is arranged so that a portion of each of the first and second cutouts is adjacent to a corner of the semiconductor chip.
he semiconductor chip further includes a third electrode;
the second electrode and the third electrode are provided on a side of the semiconductor chip opposite to that of the first electrode; and
the second electrode and the third electrode are spaced from each other.

18. The method according to claim 17, further comprising:
arranging a metallic member on the third electrode through a third connection portion, wherein the metallic member is spaced from the second metal plate.

19. The method according to claim 16, further comprising:
measuring a thickness of the second connection portion through the first cutout and the second cutout.

20. The method according to claim 16, further comprising:
measuring a position of the semiconductor chip through the first cutout and the second cutout.
